(19) United States
(12) Patent Application Publication
(10) Pub. No.: US 2009/0136875 A1
(43) Pub. Date: May 28, 2009

(54) MANUFACTURING METHOD OF LIQUID EJECTION HEAD

(75) Inventors: Masahiko Kubota, Tokyo (JP); Tamaki Sato, Kawasaki-shi (JP); Akihiko Okano, Kawasaki-shi (JP); Maki Kato, Kawasaki-shi (JP); Kazuhiro Asai, Kawasaki-shi (JP); Masaki Ohsumi, Yokosuka-shi (JP); Yoshinori Tagawa, Yokohama-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 12/268,740

(22) Filed: Nov. 11, 2008

(30) Foreign Application Priority Data
Nov. 15, 2007 (JP) 2007-296552
Mar. 25, 2008 (JP) 2008-077940

(51) Int. Cl. G03F 7/20

(52) U.S. Cl. 430/320

(57) ABSTRACT

A manufacturing method of a liquid ejection head including an ejection outlet forming member provided with an ejection outlet for ejecting liquid and a flow passage communicating with the ejection outlet is constituted by the steps of: preparing a substrate on which a flow passage wall forming member for forming a part of a wall of the flow passage and a solid layer having a shape of a part of the flow passage contact each other, wherein the flow passage wall forming member has a height, from a surface of the substrate, substantially equal to that of the solid layer; providing a first layer, on the solid layer and the flow passage wall forming member, formed of a negative photosensitive resin material for forming another part of the wall of the flow passage; exposing to light a portion of the first layer correspondingly to the another part of the wall of the flow passage; providing a second layer, on the exposed first layer, formed of a negative photosensitive resin material to constitute the ejection outlet forming member; exposing to light a portion of the second layer correspondingly to the ejection outlet forming member; and forming the ejection outlet and another part of the flow passage by removing unexposed portions of the first layer and the second layer.

### FIELD OF THE INVENTION AND RELATED ART

The present invention relates to a manufacturing method of a liquid ejection head for ejecting liquid. Specifically, the present invention relates to a manufacturing method of an ink jet recording head in which recording is carried out by ejecting ink onto a recording medium.

An example of using a liquid ejection head for ejecting liquid includes an ink jet recording head used in an ink jet recording method.

The ink jet recording head generally includes a flow passage, energy generating elements provided at a part of the flow passage, and minute ink ejection outlets for ejecting ink (also called “orifice”).

As a method of manufacturing such an ink jet recording head, U.S. Pat. No. 4,657,631 discloses the following manufacturing method. That is, a mold for the flow passage is formed of a photosensitive resin material on a substrate on which the energy generating elements are formed and then a coating resin material layer is formed on the substrate so as to coat the mold by applying the coating resin material layer constituting an ejection outlet-forming member onto the substrate. Then, ejection outlets are formed in the coating resin material layer and thereafter the photosensitive resin material used for the mold is removed to prepare the ink jet recording head.

In the case where the ink jet recording head is manufactured by the method described in U.S. Pat. No. 4,657,631, a plurality of projected ink flow passage pattern 3 may be discretely formed on a substrate 2 and in this state, a nozzle constituting material 4 may be applied onto the substrate 2. However, in this case, waviness by the influence of a stepped portion between the flow passage pattern and the substrate can occur, so that a thickness after the application is not uniform to result in a non-uniform height of an ink ejection outlet forming portion.

As a result, a distance from a heat generating resistor for ink ejection to the ink ejection outlet (═OH distance) is non-uniform in some cases.

U.S. Pat. No. 7,070,912 proposes the following method. That is, after an ink flow passage is constituted, the ink flow passage is coated with a removable resin material layer and then is flattened and then on the flattened layer, a material for constituting an ejection outlet-forming member is coated, followed by light-exposure of the ejection outlet-forming member to form an ejection outlet 6. As a result, a distance between a substrate and the ejection outlet can be ensured uniformly with respect to a plurality of ejection outlets.

However, in the method of U.S. Pat. No. 7,070,912, it can be considered that reflected light is generated at a contact interface between the removable resin material layer and the material for constituting the ejection outlet-forming member during the light-exposure for forming the ejection outlets. This reflected light affects patterning, so that it is assumed that the reflected light causes formation of a projection which is projected into the ejection outlet when the ejection outlet is completed. Further, it is also assumed that a compatible layer is formed between the removable resin material layer and the material for constituting the ejection outlet-forming member and affects a shape of a lower portion of the ejection outlet to less obtain a desired ejection outlet shape.

### SUMMARY OF THE INVENTION

The present invention has accomplished in view of the above-described problems.

A principal object of the present invention is to provide a manufacturing method capable of obtaining a liquid ejection head in which flow passages and ejection outlets are formed with good shape accuracy.

According to an aspect of the present invention, there is provided a manufacturing method of a liquid ejection head including an ejection outlet forming member provided with an ejection outlet for ejecting liquid and a flow passage communicating with the ejection outlet, the manufacturing method comprising:

preparing a substrate on which a flow passage wall forming member for forming a part of a wall of the flow passage and a solid layer having a shape of a part of the flow passage contact each other, wherein the flow passage wall forming member has a height, from a surface of the substrate, substantially equal to that of the solid layer;

providing a first layer, on the solid layer and the flow passage wall forming member, formed of a negative photosensitive resin material for forming another part of the wall of the flow passage;

exposing to light a portion of the first layer correspondingly to the another part of the wall of the flow passage;

providing a second layer, on the exposed first layer, formed of a negative photosensitive resin material to constitute the ejection outlet forming member;

exposing to light a portion of the second layer correspondingly to the ejection outlet forming member; and

forming the ejection outlet and another part of the flow passage by removing unexposed portions of the first layer and the second layer.

According to the present invention, it is possible to provide a liquid ejection head in which the flow passages and the ejection outlets have been formed with good shape accuracy, with high reproducibility.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIGS. 1(a) to 1(d) are schematic sectional views for illustrating an embodiment of the manufacturing method of an ink jet recording head according to the present invention.

FIGS. 2(a) to 2(f) are schematic sectional views for illustrating the embodiment of the manufacturing method.

FIGS. 3(a) to 3(c) are schematic sectional views for illustrating an example of a substrate of the ink jet recording head in the present invention.

FIG. 4 is a schematic perspective view for illustrating the embodiment of the manufacturing method of the ink jet recording head according to the present invention.

FIG. 5 is a schematic view for illustrating the embodiment of the manufacturing method.

FIGS. 6(a) and 6(b) are schematic sectional views for illustrating another embodiment of the manufacturing method.

### DESCRIPTION OF THE PREFERRED EMBODIMENTS

Hereinbelow, embodiments of the manufacturing method of a liquid ejection head according to the present invention will be described.

In the following description, with reference to the figures, constituent members having the same function are represented by the same reference numerals or symbols and are omitted from redundant explanation in some cases.

In the following description, an ink jet recording method will be described as an applied embodiment of the present invention. However, the present invention is not limited thereto but may also be applicable to biochip preparation, electronic circuit printing, etc.

The liquid ejection head is mountable to a printer, a copying machine, a facsimile machine including a communication system, a device such as a word processor including a printer portion, and industrial recording devices compositively combined with various processing devices. For example, the liquid ejection head can also be used for biochip preparation, electronic circuit printing, ejection of medication in the form of spray, etc. For example, by using this liquid ejection head for the purpose of recording, it is possible to carry out recording on various recording media (materials) such as paper, thread, fiber, fabric, leather, metal, plastic, glass, wood, and ceramics. Herein, “recording” means not only that a significant image such as a character image or a graphical image is provided to the recording medium but also that an insignificant image such as a pattern image is provided to the recording medium.

First, an ink jet recording head as an example of the liquid ejection head in the present invention (hereinafter, referred to as a “recording head”) will be described.

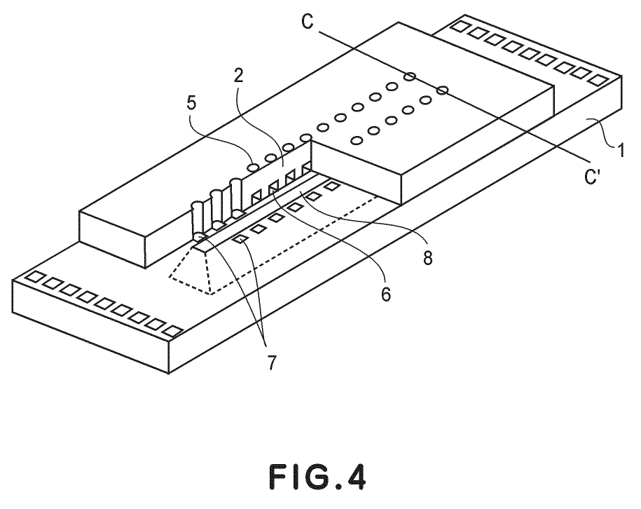

FIG. 4 is a schematic perspective view showing a recording head according to an embodiment of the present invention.

The recording head in this embodiment includes a substrate 1 on which energy generating elements 7 for generating energy utilized for ejecting ink as are formed with a predetermined pitch. The substrate 1 is provided with a supply port 8 for supplying the ink is opened between two arrays of the energy generating elements 7. On the substrate 1, ejection outlets 5 opened above associated ones of energy generating elements 7 and individual ink flow passages 6 extending from the supply port 8 and communicating with associated ones of the ejection outlets 5.

The member for forming the ejection outlets 5 also function as a flow passage-forming member 2 for forming the individual ink flow passages 6 communicating with associated ones of the ejection outlets 5.

The recording head is disposed so that a surface at which the ejection outlets 5 are formed is disposed oppositely to a recording surface of a recording medium. Then, energy generated by the energy generating elements 7 is utilized for ink filled in the flow passages through the supply port 8, thus ejecting ink droplets from the ejection outlets 5. Recording is effected by depositing these ink droplets on the recording medium. As the energy generating element, an electrothermal transducer or the like for thermal energy (so-called a heater) and a piezoelectric element or the like for mechanical energy may be used but the energy generating element is not limited to these elements.

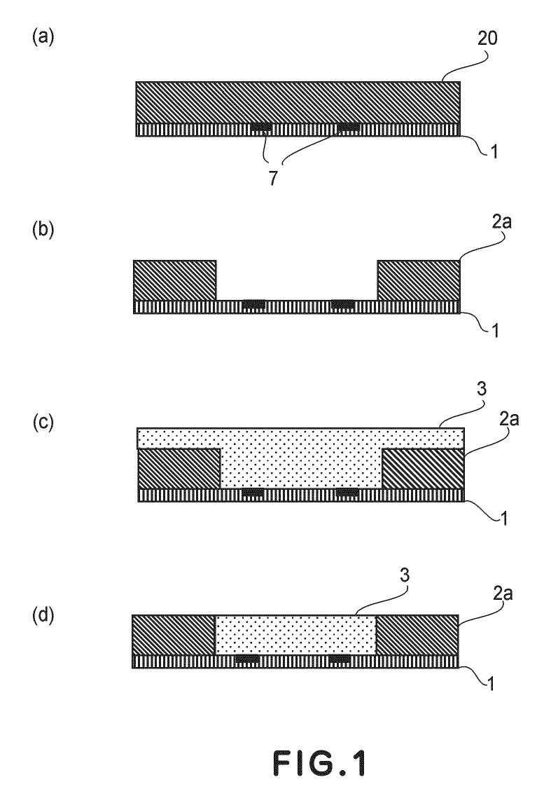

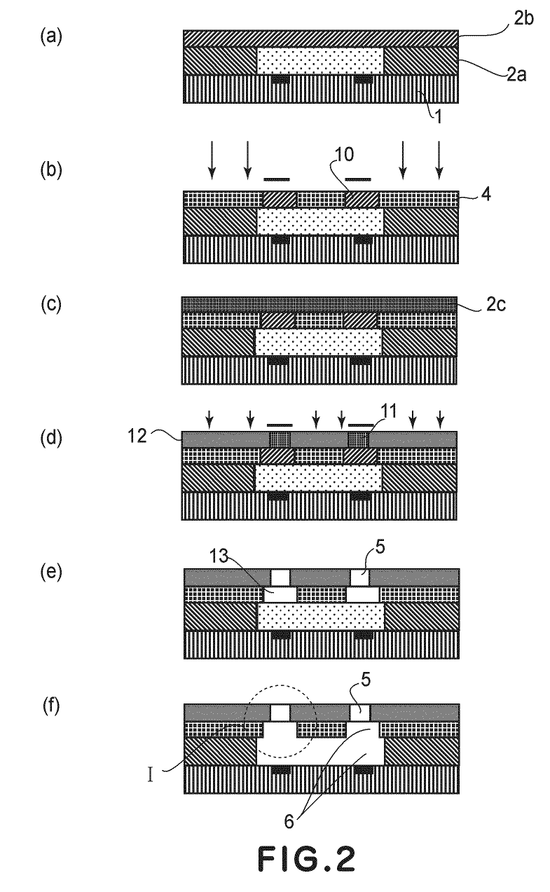

Next, features of a structure of the recording head in the present invention will be described more specifically with reference to FIGS. 1(a) to 1(d) and FIGS. 2(a) to 2(f).

FIGS. 1(a) to 1(d) are schematic sectional views, for illustrating an embodiment of the manufacturing method of the recording head according to the present invention, taken along C-C′ line shown in FIG. 4.

As shown in FIG. 1(a), a negative photosensitive resin layer 20 is formed on the substrate 1. As the substrate 1, a substrate of glass, ceramics, metal, or the like, on which an energy generating element 7 for ejecting ink is formed is used. As the energy generating element 7, the electrothermal transducer, the piezoelectric element, or the like is used but the energy generating element 7 is not limited these elements. In the case where the electrothermal transducer is used as the energy generating element, a protecting film (not shown) is formed at a surface of the energy generating element for the purpose of impact relaxation during bubble generation, alleviation of damage from the ink, and the like.

The first negative photosensitive resin layer 20 can be formed by applying a negative photosensitive resin material onto a surface of the substrate 1. As a method of applying the negative photosensitive resin material, it is possible to use a spin coating method, a direct coating method, a lamination transfer method, and the like but the application method is not limited to these methods.

As the negative photosensitive resin material used for forming the negative photosensitive resin layer 20, it is possible to use those utilizing cationic polymerization, radical polymerization, and the like but the negative photosensitive resin material is not limited to those resin materials. When the negative photosensitive resin material utilizing a cationic polymerization reaction is taken as an example, cations generated from a photo-cation polymerization initiator contained in the negative photosensitive resin material promote polymerization or cross-linking between molecules of cationically polymerizable monomers or polymer to cure the negative photosensitive resin material.

As the photo-cation polymerization initiator, it is possible to use aromatic iodonium salts, aromatic sulfonium salts, and the like. Specifically, e.g., photo-cation polymerization initiators (“ADEKA OPTOMER SP-170”, “ADEKA OPTOMER SP-150” (trade name)) are commercially available from ADEKA CORPORATION.

As the cationically polymerizable monomer or polymer, those having an epoxy group, a vinyl ether group, or an oxetone group are suitable but the monomer or polymer is not limited to these monomers or polymers. Examples thereof may include a bisphenol A epoxy resin material, a novolac epoxy resin material, an oxetane resin material such as “ARON OXETANE” (trade name, mfd. by TOAGOSEI CO., LTD.), an aliphatic epoxy resin material such as “CELLOXIDE 2021” (trade name, mfd. by DAICEL CHEMICAL INDUSTRIES, LTD.), a monoepoxide having a linear alkyl group such as “AOE” (trade name, mfd. by DAICEL CHEMICAL INDUSTRIES, LTD.), etc. Further, a multi-functional epoxy resin material described in Japanese Patent No. 3143308 exhibits a very high cationic polymerization property and a high crosslink density after curing and thus provides a cured product excellent in strength, thus being particularly preferred. As the multifunctional epoxy resin material, e.g., “EHPE-3150” (trade name, by DAICEL CHEMICAL INDUSTRIES, LTD.) and the like may be used.

Further, in order to improve application properties such as film uniformity during film formation by application, a glycol compound may preferably be contained in the negative photosensitive resin material. For example, the glycol compound may be diethylene glycol dimethyl ether or triethylene glycol methyl ether but is not limited to these compounds.

Next, as shown in FIG. 1(b), the negative photosensitive resin layer 20 is subjected to light exposure in a predetermined area and then is subjected to patterning by development to form a part of an ink flow passage wall 2a. In this step, a portion to be formed as the ink flow passage is light-blocked and an area other than the portion to be formed as the ink flow passage is irradiated with light to cure the negative photosensitive resin material, thus forming the ink flow passage wall. As developing liquid, it is possible to use methyl isobutyl ketone, a mixture solvent of methyl isobutyl ketone/xylene, and the like.

Next, as shown in FIG. 1(c), a first positive photosensitive resin layer 3 as a solid layer occupying a part of an area for constituting the flow passage is formed so as to coat the ink flow passage wall 2a. As a positive photosensitive resin material used for forming the first positive photosensitive resin layer 3, it is possible to use a resist, having a photosensitive wavelength region in the neighborhood of 290 nm, such as polymethyl isopropenyl ketone (PMIPK), polyvinyl ketone, or the like. It is also possible to use a resist, having a photosensitive wavelength region in the neighborhood of 250 nm, such as polymethyl methacrylate (PMMA) or the like.

As a forming method of the first positive photosensitive resin layer 3, it is possible to use the spin coating method, the direct coating method, and the lamination transfer method but the forming method is not limited to these methods.

Next, as shown in FIG. 1(d), the first positive photosensitive resin layer 3 is abraded until a surface of the flow passage wall 2a is exposed. As an abrading method, it is possible to use a CMP (chemical mechanical polish) technique, which is a chemical mechanical polishing method, by using slurry. In this case, the negative photosensitive resin material used for forming the flow passage wall 2a is sufficiently cross-linked by light exposure, so that the flow passage wall 2a sufficiently functions as a polishing (abrasion) stop layer by utilizing a difference in hardness between the flow passage wall 2a and the first positive photosensitive resin layer 3. As a result, it is possible to abrade the first positive photosensitive resin layer 3 so that the surface of the flow passage wall 2a and the surface of the first positive photosensitive resin layer 3 are coincide with each other. Thus, the first positive photosensitive resin layer 3 and the flow passage wall 2a has the substantially same height from the substrate 1.

As another method of flattening the first positive photosensitive resin layer 3 and the flow passage wall 2a, it is possible to use dry etching.

Through the above-described steps, the substrate on which the flow passage wall 2a for forming a part of the wall of the flow passage and the first positive photosensitive resin layer 3 as the solid layer having a shape of a part of the flow passage are provided so as to contact each other is prepared. Of a portion constituting the flow passage, the portion filled with the first positive photosensitive resin layer 3 has side surfaces substantially perpendicular to the substrate 1 since the flow passage wall 2a is formed substantially perpendicularly to the substrate 1. Further, the first positive photosensitive resin layer 3 and the flow passage wall 2a have the substantially same height from the substrate 1 and can be formed in a flat surface, so that of the flow passage-forming portion, the height of the portion filled with the first positive photosensitive resin layer 3 can be ensured with accuracy. Further, it is possible to flatly laminate a pattern of another portion of the flow passage to be formed later or a layer constituting an ejection outlet-forming member.

Next, as shown in FIG. 2(a), a first layer 2b formed of the negative photosensitive resin material is provided on the flow passage wall 2a. The negative photosensitive resin material may preferably contain a photo-cation polymerization initiator and principally comprise an epoxy resin material and may preferably be formed of a material identical to a material for forming the flow passage wall 2a. Examples of the photo-cation polymerization initiator include aromatic iodonium salts and aromatic sulfonium salts.

To the negative photosensitive resin material, a photo-cation polymerization inhibitor can be added. This photo-cation polymerization inhibitor reduces a curing property of the negative photosensitive resin material so that the compatible layer formed at the interface between the above-described positive photosensitive resin material (solid layer) and the first layer 2b formed of the negative photosensitive resin material cannot form a cured layer by exposure light. The photo-cation polymerization inhibitor may be a substance which can achieve a desired curing characteristic and a scum generation-preventing effect at a light irradiation portion and lowers a function of an acid catalyst, thus generally be a basic substance. As the basic substance, a compound capable of constituting a proton acceptor, i.e., a basic substance having a shared (covalent) electron pair may suitably be used. A nitrogen-containing compound having the shared electron pair is a compound acting on an acid as a base and is effective for preventing scum formation. Specifically, as the basic substance having the shared electron pair, compounds containing an element such as nitrogen, sulfur, or phosphorus may be used and amine compounds may be used as a representative example. Specifically, examples thereof may include amines substituted with hydroxyalkyl groups having 1-4 carbon atoms, such as diethanolamine, triethanolamine, and triisopropanolamine; pyrimidine compounds such as pyrimidine, 2-aminopyrimidine, and 4-aminopyrimidine, pyridine compounds such as pyridine and methylpyridine; and aminophenols such as 2-aminophenol and 3-aminophenol. These basic substances may also be used in mixture of two or more species.

The photo-cation polymerization inhibitor may preferably be used in an amount of 0.01-100 wt. %, more preferably 0.1-20 wt. %, in the photo-cation polymerization initiator.

Further, to the negative photosensitive resin material, it is possible to add an optical dye. As the optical dye, acridine orange which is an acridine dye or acid orange represented by the following chemical formula (1) may be used.

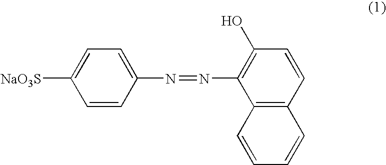

However, the optical dye is not particularly limited to the above materials so long as the optical dye has the photo-cation polymerization-inhibiting effect.

The optical dye may be added into the negative photosensitive resin material in an amount of 20 wt. % or less. By adding this optical dye, a necessary amount of electromagnetic energy is larger than that of a non-dye mixture material for cross-linking the material, so that the optical dye may preferably be added into the negative photosensitive resin material in an amount of 0.1-2 wt. %.

A pre-baking condition after the first layer 2b is applied may preferably include a temperature of 90-120° C. and a time of 3 minutes or more and 10 minutes or less.

The flow passage 2b may preferably have a thickness of 3 μm or more and 20 μm or less.

Next, as shown in FIG. 2(b), the first layer 2b is exposed to light of a wavelength range in which the first layer 2b is photosensitive, followed by baking to form an exposed portion 4 which is a latent image pattern for defining another portion of the flow passage and constitutes a part of the flow passage-forming member. An un-exposed portion 10 constitutes a part of the flow passage 6.

Next, as shown in FIG. 2(c), on the first layer 2b, a solid layer 2c formed of a negative photosensitive resin material is provided to constitute an ejection outlet-forming member. The negative photosensitive resin material for the second layer 2c may preferably be identical to those for forming the first layer 2b and the flow passage wall 2a but is not limited thereto. The second layer 2c and the first layer 2b may preferably be provided by application (coating). A baking condition of the second layer 2c may preferably be a temperature of 60° C. or more and less than 90° C.

Next, as shown in FIG. 2(d), the second layer 2c is exposed to light of a wavelength range in which the second layer 2c is photosensitive, thus forming an exposed portion 11 for constituting an ejection outlet and a cured portion 12 for constituting the ejection outlet-forming member as a latent image.

The wavelength of the light for exposure of the second layer 2c is different from a photosensitive wavelength range of the flow passage wall 2a, so that the underlying layers of the second layer 2c are not adversely affected by the light.

As a method of causing the first layer 2b to be not sensitive to the exposure light of the second layer 2c, addition of an ultraviolet absorber into either one or both of the first layer 2b and the solid layer 2c is different amounts with respect to the two layers. Further, it is also possible to contain polymerization initiators in the photosensitive resin materials constituting the first layer 2b and the second layer 2c so that the polymerization initiators have different photosensitive wavelengths.

Next, as shown in FIG. 2(e), the un-exposed portions 10 and 11 of the first layer and the second layer are exposed to light simultaneously to form an ejection outlet 5 and a portion 13 of the flow passage located under the ejection outlet 5. The ejection outlet 5 has a diameter of about 5-15 μm. The diameter is not limited to these values but these values are suitable for ejection of the minute droplets. When the ejection outlet 5 has the diameter of 5-15 μm, the flow passage portion 13 located under the ejection outlet 5 may preferably have a width of about 20 μm or more from the viewpoints of a flow resistance and a supply characteristic.

Thereafter, as shown in FIG. 2(f), a supply port (not shown) for supplying liquid to the flow passage is formed and then the positive photosensitive resin material 3 constituting the photo-degradable resin material layer is eluted to form a flow passage 6 having a partly projected cross-sectional shape as shown in FIG. 2(f).

Thereafter, a baking step for heat curing is performed and then electrical connection (not shown) for driving the heat generating resistor 7 is established to complete the liquid ejection recording head.

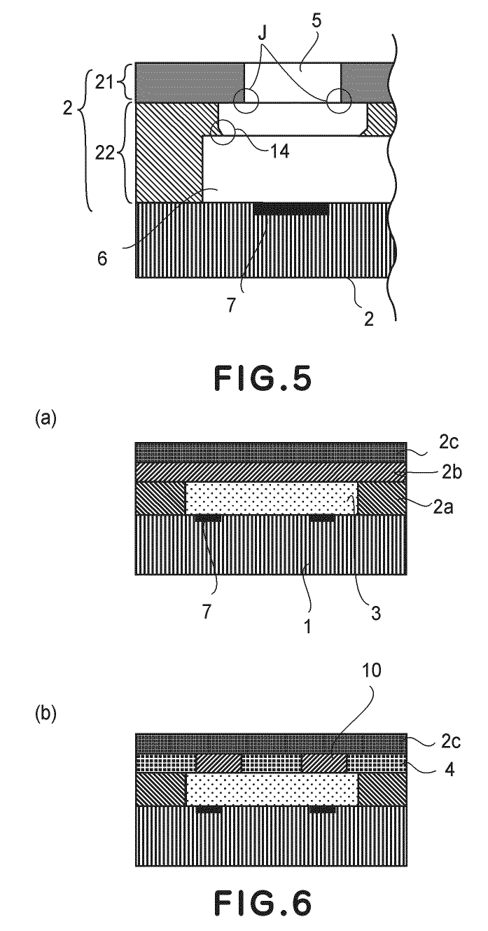

The thus-manufactured recording head of FIG. 2(f) is shown in FIG. 5 as a partly enlarged view. As shown in FIG. 5, of the flow passage-forming member, at a portion which was the interface between the first layer 2b and the solid layer 3, a minute projection-like portion 14 is slightly formed in some cases. On the other hand, on the substrate surface side (J in FIG. 5) of the ejection outlet-forming member 2 for forming the ejection outlet 5, there is no minute projection-like portion. This may be attributable to such a phenomenon that the first layer 2b of the negative photosensitive resin material and the solid layer 3 of the positive photosensitive resin material are compatibilized in the step shown in FIG. 2(a) and a part of the compatibilized portion remains as the minute projection-like portion without being dissolved in the developing liquid for the first layer 2b during the development of the first layer 2b as shown in FIG. 2(e).

On the other hand, in the case where the first layer 2b and the second layer 2c are formed of the negative photosensitive resin materials including the same base resin material, the respective un-exposed portions 10 and 11 are developed collectively by a single developing liquid. Even when the first layer 2b and the second layer 2c are compatibilized, the compatibilized portion is dissolved in the developing liquid for the first layer 2b and the second layer 2c, so that the minute projection-like portion 14 is not formed.

For the ejection, the shape of the ejection outlet 5, which largely affects the ejection characteristic, on the substrate surface side is formed with accuracy, so that it is possible to minimize the influence of the ejection outlet shape although there is asymmetry such that the ink in the flow passage 6 accesses the ejection outlet 5 in one direction. Specifically, it is possible to minimize deviation or the like of a droplet ejection direction and also minimize a lowering in refilling frequency caused by abstraction of flow during the refilling of the liquid (ink).

For example, in the case where the ejection outlet has a minute shape having a diameter of 15 μm or less, when the minute projection-like portion 14 formed below the ejection outlet is about 1 μm in size, it is assumed that the ejection is influenced. In the present invention, in the case where the minute projection-like portion 14 can be formed, the formed portion is located at the position which was the interface between the first layer 2b and the solid layer 3 which constitute the flow passage-forming member 2. The interface is located at a lower portion of the flow passage upper portion 13, so that the influence of the minute projection-like portion 14 on the flow resistance or the like is small in a large-volume flow passage.

Hereinbelow, the present invention will be described in further detail based on several specific embodiments.

### Embodiment 1

First, on the substrate 1 provided with heat generating resistors 7 as an energy generating element, a negative photosensitive resin material consisting of Composition 1 shown below was spin-coated in a thickness of 10 μm, followed by pre-baking on a hot plate at 90° C. for 3 minutes to form a negative photosensitive resin layer 20 (FIG. 1(a)).

### <Composition 1>

| | |
|---|---|
| Epoxy resin (“EHPE”, mfd. by DAICEL CHEMICAL | 100 wt. parts |
| INDUSTRIES, LTD.) | |
| Additive (“1,4-HFAB”, mfd. by Central Glass Co., | 20 wt. parts |
| Ltd.) | |
| Photo-cation polymerization initiator (“SP-170”, | 2 wt. parts |
| mfd. by ADEKA CORPORATION) | |
| Catalyst (“A-187”, mfd. by Nippon Unicar Co., | 5 wt. parts |
| Ltd.) | |
| Solvent (methyl isobutyl ketone) | 100 wt. parts |
| Solvent (diglyme) | 100 wt. parts |

Next, the negative photosensitive resin layer 20 was exposed to light of a wavelength of 290-400 nm at an exposure amount of 500 mJ/cm² by using an aligner (“MPA-600”, mfd. by Canon Kabushiki Kaisha) and then was subject to PEB (post exposure bake) at 90° C. for 4 minutes, followed by development using a mixture liquid of methyl isobutyl ketone/xylene=2/3. By the development, the exposed area remained, thus forming a flow passage wall 2a (FIG. 1(b)).

Next, a photo-degradable resin material (“ODUR”, mfd. by TOKYO OHKA KOGYO CO., LTD.) was spin-coated in a thickness of 15 μm so as to coat the substrate 1 and the flow passage wall 2a and then was pre-baked on the hot plate of 120° C. for 3 minutes to form a solid layer 3 (FIG. 1(c)).

Next, the solid layer 3 was abraded by CMP. The abrasion of the solid layer 3 was carried out so as to expose the flow passage wall 2a to form a flattened layer consisting of the solid layer 3 and the flow passage wall 2a (FIG. 1(d)).

Next, on the flattened layer, the above-described negative photosensitive resin material consisting of Composition 1 was spin-coated in a thickness of 5 μm, followed by pre-baking on the hot plate at 90° C. for 3 minutes to form a first layer 2b (FIG. 2(a)).

Next, the first layer 2b is exposed to light of a wavelength of 290-440 nm at an exposure amount of 500 mJ/cm² by using the aligner (“MPA-600”, mfd. by Canon Kabushiki Kaisha), followed by PEB at 90° C. for 4 minutes. As a result, the exposed area was cured to provide a cured portion 4 (FIG. 2(b)).

Then, on the cured portion 4, a dry film of a negative photosensitive resin material consisting of Composition 2 shown below was laminated in a thickness of 10 μm as a second layer 2c. The lamination was performed under a condition including a pressure of 0.5 MPa, a temperature of 50° C., and a speed of 0.1 m/min (FIG. 2(c)).

### <Composition 2>

| | |
|---|---|
| Epoxy resin (“EHPE, mfd. by DAICEL CHEMICAL | 100 wt. parts |
| INDUSTRIES, LTD.) | |
| Additive (“1,4-HFAB”, mfd. by Central Glass Co., | 20 wt. parts |
| Ltd.) | |
| Photo-cation polymerization initiator (“SP-172”, | 6 wt. parts |
| mfd. by ADEKA CORPORATION) | |
| Catalyst (“A-187”, mfd. by Nippon Unicar Co., | 5 wt. parts |
| Ltd.) | |
| Solvent (xylene) | 200 wt. parts |

The photo-cation polymerization initiator (SP-172) in Composition 2 was different in photosensitive wavelength from the photo-cation polymerization initiator (SP-170) in Composition 1.

Then, the second layer 2c was exposed to light of a wavelength of 365 nm at an exposure amount of 2500 mJ/cm² by using an aligner (“FPA-30001W”, mfd. by Canon Kabushiki Kaisha), followed by PEB at 90° C. for 4 minutes to form a cured portion 12 so as to define ejection outlets each having a diameter of 10 μm (FIG. 2(d)).

Next, development using a mixture liquid of methyl isobutyl ketone/xylene=2/3 and rinsing with xylene were carried out to form ejection outlets 5 and a part (portion) 13 of a flow passage (FIG. 2(e)).

Then, a supply port (not shown), for supplying liquid, which had passed through the substrate 1 and had reached the solid layer 3 was formed and thereafter the solid layer 3 was exposed to light at an exposure amount of 30000 mJ/cm² by using an aligner (“UX-3000”, mfd. by USHIO INC.). Thereafter, the solid layer 3 was eluted with methyl lactate through the supply port under application of ultrasonic wave to form a flow passage 6 (FIG. 2(f)).

In this way, a recording head was prepared.

In this embodiment, the first layer 2b and the second layer 2c employed the same base resin material but were different from each other in photosensitive wavelength of the photo-cation polymerization initiator contained in the negative photosensitive resin material. Therefore, i-ray used for exposing the second layer 2c can be given by light of a different wavelength. The photo-cation polymerization initiator (SP-172) contained in the first layer 2b has a sufficiently weak photosensitivity to the light of the wavelength of 365 nm used during the exposure of the second layer 2c, so that the first layer 2b is not exposed to the light during the exposure of the second layer 2c.

### Embodiment 2

Until the step shown in FIG. 2(a), the manufacturing method of the recording head was performed in the same manner as in Embodiment 1.

Then, on the first layer 2b, the second layer 2c was formed of Composition 2 by spin coating, followed by pre-baking (FIG. 6(a)).

Next, the first layer 2b was exposed to the light of the wavelength of 290-400 nm, followed by baking to form a cured portion 4 as a part of a flow passage-forming member (FIG. 6(b)).

Next, the second layer 2c was exposed to the light of the wavelength of 365 nm, followed by baking to form a cured portion 12 as an ejection outlet-forming member (FIG. 2(d)).

Thereafter, the manufacturing method was carried out in the same manner as in Embodiment 1.

In this embodiment, the first layer 2b has a low photosensitivity to the light of the wavelength of 365 nm used for exposing the second layer 2c, so that an unexposed portion 10 of the first layer 2b is not photosensitive to the light. Therefore, it is possible to form the flow passage with shape accuracy.

### Embodiment 3

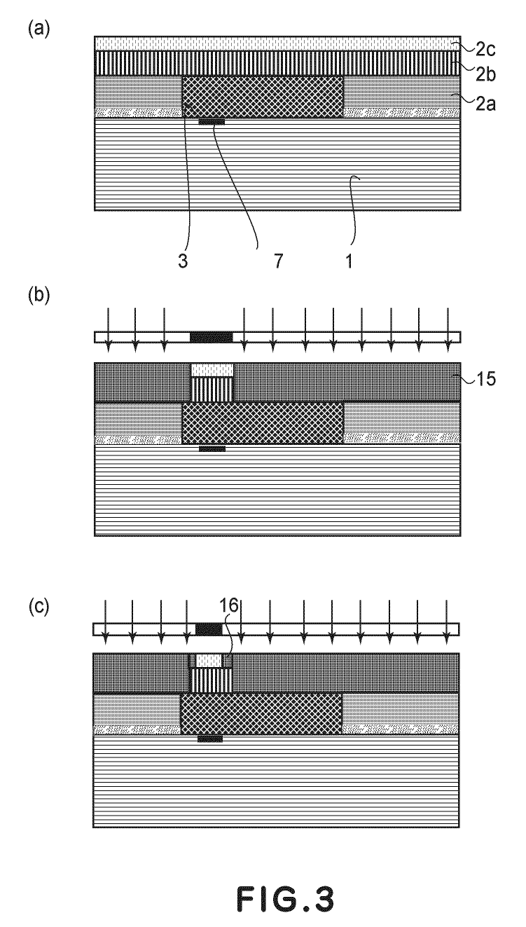

A manufacturing method of a recording head will be described with reference to FIGS. 3(a) to 3(c) which are schematic sectional views similar to FIGS. 1(a) to 1(d).

Until the step shown in FIG. 2(a), the manufacturing method was performed in the same manner as in Embodiment 1.

Next, a negative photosensitive resin layer having low photosensitivity was formed as the first layer 2b in a thickness of 3 μm by spin coating and then a negative photosensitive resin layer having high photosensitivity was formed as the second layer 2c in a thickness of 10 μm by spin coating.

The first layer 2b was formed of the following photocurable composition.

| | | |
|---|---|---|
| EHPE-3150 (cation-polymerizable compound) (trade | 50 | wt. parts |
| name, mfd. by DAICEL CHEMICAL INDUSTRIES, | | |
| LTD.) | | |
| SP-172 (photo-cation polymerization initiator) | 1 | wt. part |
| (trade name, mfd. by ADEKA CORPORATION) | | |
| A-187 (silane coupling agent) (trade name, mfd. by | 2.5 | wt. parts |
| Nippon Unicar Co., Ltd.) | | |

To these ingredients, triethanol amine (photo-cation polymerization inhibitor) was added in an amount of 0.01 mol. % of the photo-cation polymerization initiator (SP-172). The resultant mixture was dissolved in 50 wt. parts of xylene (application solvent) to prepare the photocurable composition.

The second layer 2c was formed of the following photocurable composition.

| | | |
|---|---|---|
| EHPE-3150 (cation-polymerizable compound) (trade | 50 | wt. parts |
| name, mfd. by DAICEL CHEMICAL INDUSTRIES, | | |
| LTD.) | | |
| SP-172 (photo-cation polymerization initiator) | 1 | wt. part |
| (trade name, mfd. by ADEKA CORPORATION) | | |
| A-187 (silane coupling agent) (trade name, mfd. by | 2.5 | wt. parts |
| Nippon Unicar Co., Ltd.) | | |

These ingredients were dissolved in 50 wt. parts of xylene (application solvent) to prepare the photocurable composition.

The first layer 2b and the second layer 2c were exposed to light at an exposure amount of 800 mJ/cm² by using a projection exposure machine (“MPA Super 600”, mfd. by Canon Kabushiki Kaisha) to form a cured portion 15 (FIG. 3(b)). This exposure amount is capable of photosensitizing the first layer 2b and the second layer 2c at the same time.

The first layer 2b and the second layer 2c were further exposed to light in an area other than an ejection outlet-forming area at an exposure amount of 100 mJ/cm² by using a projection exposure machine (“MPA Super 600”, mfd. by Canon Kabushiki Kaisha) to form a cured portion 16 (FIG. 3(c)). This exposure amount is capable of photosensitizing only the second layer 2c.

Incidentally, in the case of forming the ejection outlet-forming portion (cured portion) 16 by selectively curing the second layer 2c, the following relationship may preferably be employed. That is, the exposure amount during the formation of the ejection outlet-forming portion 16 may preferably be ⅙, more preferably 1/20, of the exposure amount during the simultaneous exposure of the first layer 2b and the second layer 2c although it varies depending on a material (type) of the negative photosensitive resin material.

Subsequent steps can be performed in the same manner as in Embodiment 2.

### Embodiment 4

Embodiment 4 is different from Embodiment 3 in the following points.

As the material for the first layer 2b, a photocurable composition prepared by mixing a 5 μm-thick layer-formable epoxy resin material (“SU8” (trade name)) with an optical dye (acid orange: 2 wt. %) was used. By adding such an optical dye, an amount of energy required for cross-linking is larger than that of a material containing no optical dye.

As the material for the second layer 2c, the 5 μm-thick layer-formable epoxy resin material (“SU8” (trade name)) was used.

In the step shown in FIG. 3(b), the exposure amount was changed to 600 mJ/cm².

In the step shown in FIG. 3(c) in this embodiment, the light for selective exposure of the second layer 2c is absorbed by the first layer 2b even when it passes through the second layer 2c.

Other steps were performed in the same manner as in Embodiment 3.

### Embodiment 5

Embodiment 5 is different from Embodiment 4 in the following points.

The first layer 2b was formed, in a thickness of 10 μm, of the following photocurable composition.

| | | |
|---|---|---|
| EHPE-3150 (cation-polymerizable compound) (trade | 50 | wt. parts |
| name, mfd. by DAICEL CHEMICAL INDUSTRIES, | | |
| LTD.) | | |
| SP-172 (photo-cation polymerization initiator) | 1 | wt. part |
| (trade name, mfd. by ADEKA CORPORATION) | | |
| A-187 (silane coupling agent) (trade name, mfd. by | 2.5 | wt. parts |
| Nippon Unicar Co., Ltd.) | | |

To these ingredients, triethanol amine (photo-cation polymerization inhibitor) was added in an amount of 0.01 mol. % of the photo-cation polymerization initiator (SP-172) and 2 wt. parts of an optical dye (orange acid) having a photo-cation polymerization inhibiting effect was added. The resultant mixture was dissolved in 50 wt. parts of xylene (application solvent) to prepare the photocurable composition.

The second layer 2c was formed, in a thickness of 2 μm, of the following photocurable composition.

| | | |
|---|---|---|
| EHPE-3150 (cation-polymerizable compound) (trade | 50 | wt. parts |
| name, mfd. by DAICEL CHEMICAL INDUSTRIES, | | |
| LTD.) | | |
| SP-172 (photo-cation polymerization initiator) | 1 | wt. part |
| (trade name, mfd. by ADEKA CORPORATION) | | |
| A-187 (silane coupling agent) (trade name, mfd. by | 2.5 | wt. parts |
| Nippon Unicar Co., Ltd.) | | |

These ingredients were dissolved in 50 wt. parts of xylene (application solvent) to prepare the photocurable composition.

Further, in the step shown in FIG. 3(b), the exposure amount was changed to 1600 mJ/cm² and in the step shown in FIG. 3(c), the exposure amounts was changed to 80 mJ/cm².

Other steps were performed in the same manner as in Embodiment 3.

In the above-described Embodiments 1 to 5, the shapes of the recording heads in the neighborhood of the ejection outlets were formed with accuracy.

While the invention has been described with reference to the structures disclosed herein, it is not confined to the details set forth and this application is intended to cover such modifications or changes as may come within the purpose of the improvements or the scope of the following claims.

This application claims priority from Japanese Patent Application No. 296552/2007 filed Nov. 15, 2007, and 077940/2008 filed Mar. 25, 2008, which is hereby incorporated by reference.

What is claimed is:

1. A manufacturing method of a liquid ejection head including an ejection outlet forming member provided with an ejection outlet for ejecting liquid and a flow passage communicating with the ejection outlet, said manufacturing method comprising:
preparing a substrate on which a flow passage wall forming member for forming a part of a wall of the flow passage and a solid layer having a shape of a part of the flow passage contact each other, wherein the flow passage wall forming member has a height, from a surface of the substrate, substantially equal to that of the solid layer;
providing a first layer, on the solid layer and the flow passage wall forming member, formed of a negative photosensitive resin material for forming another part of the wall of the flow passage;
exposing to light a portion of the first layer correspondingly to said another part of the wall of the flow passage;
providing a second layer, on the exposed first layer, formed of a negative photosensitive resin material to constitute the ejection outlet forming member;
exposing to light a portion of the second layer correspondingly to the ejection outlet forming member; and
forming the ejection outlet and another part of the flow passage by removing unexposed portions of the first layer and the second layer.

2. A method according to claim 1, wherein the first layer and the second layer cation the same resin material.

3. A method according to claim 1, wherein the first layer and the second layer contain the same epoxy resin material.

4. A method according to claim 1, wherein the first layer contains a first photo-cation polymerization initiator and the second layer contains a second photo-cation polymerization initiator which is different in photosensitive wavelength from the first photo-cation polymerization initiator, and
wherein the light for the exposure of the first layer and the light for the exposure of the second layer and different in wavelength range from each other.

5. A manufacturing method of a liquid ejection head including an ejection outlet forming member provided with an ejection outlet for ejecting liquid and a flow passage communicating with the ejection outlet, said manufacturing method comprising:
preparing a substrate on which a flow passage wall forming member for forming a part of a wall of the flow passage and a solid layer having a shape of a part of the flow passage contact each other, wherein the flow passage wall forming member has a height, from a surface of the substrate, substantially equal to that of the solid layer;
providing a first layer, on the solid layer and the flow passage wall forming member, formed of a negative photosensitive resin material for forming another part of the wall of the flow passage;
exposing to light a portion of the first layer correspondingly to said another part of the wall of the flow passage, the light having passed through the second layer;
providing a second layer, on the exposed first layer, formed of a negative photosensitive resin material to constitute the ejection outlet forming member;
exposing to light a portion of the second layer correspondingly to the ejection outlet forming member; and
forming the ejection outlet and another part of the flow passage by removing unexposed portions of the first layer and the second layer.

6. A method according to claim 5, wherein the first layer contains a first photo-cation polymerization initiator and the second layer contains a second photo-cation polymerization initiator which is different in photosensitive wavelength from the first photo-cation polymerization initiator, and
wherein the light for the exposure of the first layer and the light for the exposure of the second layer and different in wavelength range from each other.

7. A manufacturing method of a liquid ejection head including an ejection outlet forming member provided with an ejection outlet for ejecting liquid and a flow passage communicating with the ejection outlet, said manufacturing method comprising:
preparing a substrate on which a flow passage wall forming member for forming a part of a wall of the flow passage and a solid layer having a shape of a part of the flow passage contact each other, wherein the flow passage wall forming member has a height, from a surface of the substrate, substantially equal to that of the solid layer;
providing a first layer, on the solid layer and the flow passage wall forming member, formed of a negative photosensitive resin material for forming another part of the wall of the flow passage;
providing a second layer, on the exposed first layer, formed of a negative photosensitive resin material to constitute the ejection outlet forming member;
simultaneously exposing to light both of a portion of the first layer correspondingly to said another part of the wall of the flow passage and a portion of the second layer correspondingly to the ejection outlet forming member; and
exposing to light a portion of the second layer correspondingly to the ejection outlet.

8. A method according to claim 7, wherein the first layer contains a light-absorbing material for absorbing the light for the exposure of the portion of the second layer correspondingly to the ejection outlet.
